(19) United States
(12) Patent Application Publication
(10) Pub. No.: US 2026/0219351 A1
(43) Pub. Date: Jul. 30, 2026

(54) ADAPTER FOR USE IN TESTING AN ENERGY METER

(71) Applicant: Landis+Gyr Technology, Inc., Alpharetta, GA (US)

(72) Inventors: Matthew Eric KRAUS, Jamestown, IN (US); Frank J. BOUDREAU, JR., Lafayette, IN (US)

(21) Appl. No.: 19/142,789

(22) PCT Filed: Dec. 20, 2023
(86) PCT No.: PCT/US2023/085170

§ 371 Date: Jun. 24, 2025

Related U.S. Application Data
(60) Provisional application No. 63/435,610, filed on Dec. 28, 2022.

(51) Int. Cl. G01R 35/04; G01R 21/00

(52) U.S. Cl. CPC G01R 35/04; G01R 21/007

(57) ABSTRACT

An adapter for coupling a three-port meter to a three-phase meter test board is disclosed. The adapter comprises a first interface for coupling to the three-phase meter test board, and a second interface for coupling to the three-port meter. Also disclosed is a meter test system comprising: a three-phase meter test board; and the adapter, wherein the adapter is received by the three-phase meter test board and configured to receive the three-port meter. An associated method of testing a three-port meter using a three-phase meter test board is also disclosed.

### FIELD OF INVENTION

The disclosure is in the field of adapters for coupling meters to meter test boards for testing the meters, and relates in particular to adapter for coupling three-port meters to a three-phase meter test boards.

### BACKGROUND

Distributed energy resource (DER) devices may include, for example, solar panels, wind turbines, electric vehicle batteries, generators, etc. There is a general trend towards an increase in use of DER devices by energy consumers, including residential consumers.

In a resource distribution system, such as an electric grid that delivers electric power, a meter may be used to measure and control consumption at a customer premises. The meter may include metrology components for measuring consumption and monitoring power characteristics and communications components for communicating with other devices on a network, as well as a central system, such as a head-end system. The meter may also include other modules and components.

When a DER device is located at residential premises, the power generated or stored by the DER device may be metered by a multi-port meter and used at the premises or output to the electric grid.

To accommodate DER at residential premises, a new type of meter has been proposed that comprises multiple ports for connecting the DER to the grid and to the customer. This new meter form 43S, as defined in the ANSI C12.10 specification, has the capability to shed the DER from the Grid and allow customer Islanding in the case of solar generation or to shed an electric car charging station without disconnecting the customer.

It is known to test and/or calibrate meters, such as in production, installation or even at end-of life, by installing said meters on meter test boards configured to simulate typical usage of the meters.

However, common 3-phase meter test apparatuses may comprise insufficient features and/or may be incorrectly configured for testing the new meter form 43S. Common 3-phase meter test apparatuses may be relatively expensive.

As such, it is desirable to provide a relatively low-cost and reliable means to test the new meter form 43S. Such means must be safe, reliable and must not be prohibitively expensive and/or resource-intensive to implement.

It is therefore an aim of at least one embodiment of at least one aspect of the present disclosure to obviate or at least mitigate at least one of the above identified shortcomings of the prior art.

### SUMMARY OF INVENTION

The present disclosure is in the field of adapters for coupling meters to meter test boards for testing the meters, and relates in particular to adapter for coupling three-port meters to a three-phase meter test boards. According to a first aspect of the disclosure, there is provided an adapter for coupling a three-port meter to a three-phase meter test board. The adapter comprises: a first interface for coupling to the three-phase meter test board; and a second interface for coupling to the three-port meter.

The adapter comprises first and second conductive elements for coupling first and second a-phase current source terminals of the first interface to a first line port terminal and a first load port terminal of the second interface respectively.

The adapter comprises third and fourth conductive elements for coupling first and second c-phase current source terminals of the first interface to a second line port terminal and a second load port terminal of the second interface respectively.

The adapter comprises a fifth conductive element for coupling a first distributed energy resource (DER) port terminal of the second interface to a second DER port terminal of the second interface.

The adapter comprises sixth and seventh conductive elements for coupling first and second b-phase current source terminals of the first interface to the first and second terminals of the line port respectively or to the first and second terminals of the load port respectively.

Advantageously, the disclosed adapter or adapters allow a test board that only has three current elements to simultaneously send current from the line (grid), through both the load port and the DER port of the three-port meter. Advantageously, the test board is able to get accurate energy measurements because it is sending current through the DER port using what would traditionally be the third current element for a three phase service. That is, the disclosed adapter(s) effectively enable simultaneously testing of a flow of energy through all of the ports of a three-port meter simultaneously.

The adapter may comprise at least one switch, e.g. at least one relay or the like, for selectively configuring the adapter between: a first configuration for coupling the first and second b-phase current source terminals of the first interface to the first and second terminals of the line port respectively; or a second configuration for coupling the first and second b-phase current source terminals of the first interface to the first and second terminals of the load port respectively.

The adapter may be configured to couple an a-phase voltage source of the first interface to the second interface by coupling the first a-phase current source terminal to a first terminal of a first potential link, wherein a second terminal of the first potential link is selectively coupled to the first line port terminal.

The adapter may be configured to couple a c-phase voltage source of the first interface to the second interface by coupling the first c-phase current source terminal to a first terminal of a second potential link, wherein a second terminal of the second potential link is selectively coupled to the second line port terminal.

The adapter may comprise a further conductive element configured to couple a neutral terminal of the first interface to a neutral terminal (230 g, 330 g) of the second interface.

The first interface may comprises a plurality of blades for being received by a meter socket on the three-phase meter test board, each blade coupled to one of the first to seventh conductive elements.

The second interface may comprise a plurality of sockets for received blades of the three-phase meter, each socket coupled to one of the first to seventh conductive elements.

According to a second aspect of the disclosure, there is provided a meter test system comprising: a three-phase meter test board; and an adapter according to the first aspect. The adapter may be received by the three-phase meter test board and configured to receive the three-port meter.

The three-phase meter test board may comprise an a-phase current source, a b-phase current source and a c-phase current source, and wherein the current sources are floating and electrically isolated from each other.

The meter test system may comprise the three-phase meter.

The three-phase meter may conform to meter form 43S as defined by the American National Standard for Physical Aspects of Watt-hour Meters (ANSI) C12.10.

According to a third aspect of the disclosure, there is provided a method of testing a three-port meter using a three-phase meter test board, the method comprising using an adapter according to any preceding claim to couple the three-port meter to a three-phase meter test board.

The method may comprising a step of configuring the adapter in a first configuration for coupling the first and second b-phase current source terminals of the first interface to the first and second terminals of the line port respectively.

The method may comprising a step of configuring the adapter in a second configuration for coupling the first and second b-phase current source terminals of the first interface to the first and second terminals of the line port respectively.

The method may comprise configuring a-phase, b-phase and c-phase current sources of the three-phase meter test board to simulate a simultaneous flow of energy from the DER port to the line port of the meter and the line port to the load port of the meter.

The method may comprise configuring a-phase, b-phase and c-phase current sources of the three-phase meter test board to simulate a simultaneous flow of energy from the DER port to the load port of the meter and the line port to the load port of the meter.

The method may comprise a step, e.g. a preceding step, of configuring a/the first potential link and/or a/the second potential link of the adapter to avoid a short circuit through the b-phase current source.

The above summary is intended to be merely exemplary and non-limiting. The disclosure includes one or more corresponding aspects, embodiments or features in isolation or in various combinations whether or not specifically stated (including claimed) in that combination or in isolation. It should be understood that features defined above in accordance with any aspect of the present disclosure or below relating to any specific embodiment of the disclosure may be utilized, either alone or in combination with any other defined feature, in any other aspect or embodiment or to form a further aspect or embodiment of the disclosure.

### BRIEF DESCRIPTION OF DRAWINGS

These and other aspects of the present disclosure will now be described, by way of example only, with reference to the accompanying drawings, wherein:

FIG. 1 depicts a Form 43S meter;

FIG. 2 depicts a proposed solution for testing all ports of a Form 43S meter;

FIG. 3 depicts a method of testing ports of a Form 43S meter, according to an embodiment of the disclosure;

FIG. 4 depicts a configuration of an adapter for implementing the method of FIG. 3, according to an embodiment of the disclosure;

FIG. 5 depicts a further method of testing ports of a Form 43S meter, according to an embodiment of the disclosure; and

FIG. 6 depicts a configuration of an adapter for implementing the method of FIG. 5, according to an embodiment of the disclosure.

### DETAILED DESCRIPTION OF DRAWINGS

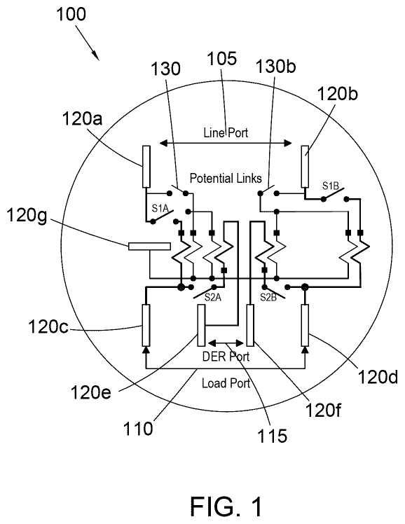

FIG. 1 depicts an example of a Form 43S three-port meter 100. The example three-port meter 100 comprises a line port 105, also known in the art as a grid port. In use, the line port 105 may be coupled to the electrical grid.

The example three-port meter 100 comprises a load port 110. In use, the load port 110 may be coupled to a load, for example an electrical energy consuming load at a premises, such as air conditioning, heating, or the like.

The example three-port meter 100 comprises a “DER port” 115. In use, the DER port 115 may be coupled to a distributed energy resource such as, for example, solar panels, wind turbines, electric vehicle batteries, generators, etc.

The example three-port meter 100 comprises a plurality of blades 120a-g. In use, the example three-port meter 100 may be inserted in a meter socket (not shown), and the blades 120a-g may be received in corresponding sockets of the meter socket.

In use of the example three-port meter 100, two blades 120a, 120b are coupled to the line port 105, two blades 120c, 120d are coupled to the load port 110, two blades 120e, 120f are coupled to the DER port 115, and a further blade 120g is coupled to neutral.

The example three-port meter 100 comprises circuitry 125 comprising various current transformers for measuring/metering each phase of a flow of electrical current through the ports, and voltage transformers for measuring/metering each phase of a voltage.

The example three-port meter 100 also comprises potential links 130a, 130b, also known as “test links” for disconnecting a voltage source during testing to avoid short circuiting through a current source.

The example three-port meter 100 also comprise disconnects, denoted S1A, S1B, S2A, S2C. Such disconnects S1A, S1B, S2A, S2C may be implemented as relays. The disconnects S1A, S1B, S2A, S2C may be used to shed a load or a supply. For example, disconnect S1A and S2A may be opened to shed the grid coupled to the line port 105, or disconnects S2A and S2B may be opened to shed a DER coupled to the DER port 115.

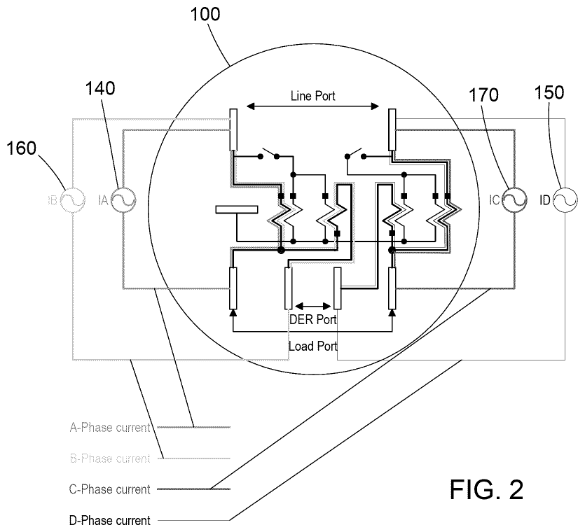

Methods and apparatuses for testing such a three-port meter 100 are now described with reference to FIGS. 2 to 6.

To test such a three-port, e.g. line, load and DER port, using conventional methods, four current sources may be required. This is depicted in FIG. 2, which shows a hypothetical meter testing scenario. In this example, the example three-port meter 100 is tested using: an a-phase current source 140 coupled between blade 120a of the line port 105 and blade 120e of the DER port 115; a d-phase current source 150 coupled between blade 120b of the line port 105 and blade 120f of the DER port 115, a b-phase current source 160 coupled between blade 120b of the line port 105 and blade 120c of the load port 110; and a c-phase current source 170 coupled between blade 120b of the line port 105 and blade 120d of the load port 110.

That is, to be able to simulate a simultaneous flow of energy from the DER port to the line port 105 of the meter and the line port 105 to the load port 110 of the meter, and to also be able to simulate a simultaneous flow of energy from the DER port to the load port 110 of the meter and the line port 105 to the load port 110 of the meter, a test board comprising a total of four current sources would be required. Such a test-board implementation may be prohibitively expensive to implement.

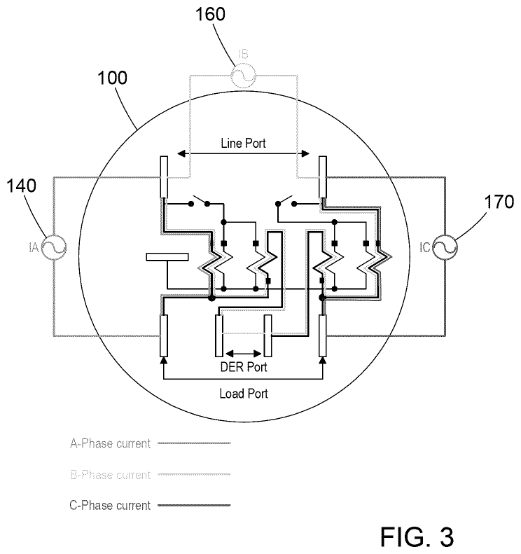

FIG. 3 depicts a method of testing the example three-port meter 100 wherein, in order to test the three-port meter, e.g. a form 43S meter, an adapter can be used to route the currents in a particular fashion that will emulate a common use of a three-port meter.

Such a method advantageously enables existing three-phase test boards and 3-phase reference standards that are widely used to test the three-port meter without a necessity for a new 4-phase reference standard and test board.

In this method, an adapter 200 is implemented to use the existing B-phase current element and direct it across blades 120a and 120c of the line port 105. The existing a-phase current element is provided across blade 120a of the load port 110 and blade 120c of the load port 110. Blades 120e and 120f of the DER port 115 are shorted together. In the case that the grid port is closed the DER would be as a 240V source or load and the current through it would be equal. Thus, the 4^{th} independent current phase is not required, as depicted in FIG. 2.

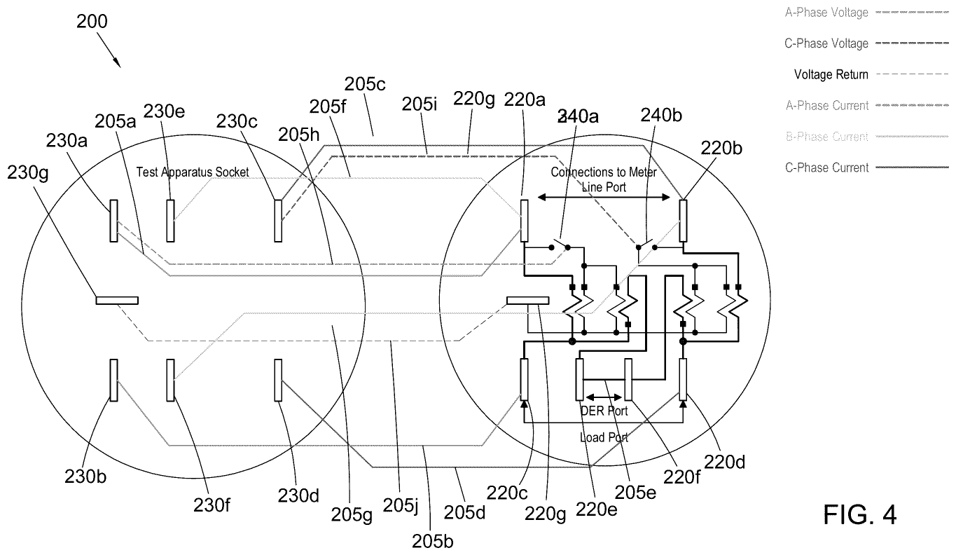

FIG. 4 depicts a configuration of an adapter 200 for implementing the method of FIG. 3, according to an embodiment of the disclosure. FIG. 4 represents an adapter 200 for coupling a three-port meter 100 to a three-phase meter test board.

The adapter 200 comprises a first interface for coupling to the three-phase meter test board, e.g. denoted “Test apparatus Socket” in FIG. 4. The adapter 200 comprises a second interface for coupling to the three-port meter, as denoted “Connection to meter” in FIG. 4.

The adapter 200 comprises a first conductive element 205a for coupling a first a-phase current source terminal 230a of the first interface to a first line port terminal 220a of the second interface.

The adapter 200 comprises a second conductive element 205b for coupling a second a-phase current source terminal 230b of the first interface to a first load port terminal 220c of the second interface.

The adapter 200 comprises a third conductive element 205c for coupling a first c-phase current source terminal 230c of the first interface to a second line port terminal 220b of the second interface.

The adapter 200 comprises a fourth conductive element 205d for coupling a second c-phase current source terminal 230d of the first interface to a second load port terminal 220d of the second interface.

The adapter 200 comprises a fifth conductive element 205e for coupling a first distributed energy resource (DER) port terminal 220e of the second interface to a second DER port terminal 220f of the second interface.

The adapter 200 comprises a sixth conductive element 205f for coupling a first b-phase current source terminal 230e of the first interface to the first terminal 220a of the line port.

The adapter 200 comprises a seventh conductive element 205g for coupling a second b-phase current source terminal 230f of the first interface to the second terminal 220c of the line port.

In some examples, the adapter 200 also comprises an eighth conductive element 205h configured to couple an a-phase voltage source of the first interface to the second interface by coupling the first a-phase current source terminal 230a to a first terminal of a first potential link 240a, wherein a second terminal of the first potential link 240a is selectively coupled to the first line port terminal 220a.

In some examples, the eighth conductive element 205h may be at least partly combined with, on integral to, the first conductive element 205a.

In some examples, the adapter 200 also comprises a ninth conductive element 205i configured to couple a c-phase voltage source of the first interface to the second interface by coupling the first c-phase current source terminal 230c to a first terminal of a second potential link 240b, wherein a second terminal of the second potential link 240b is selectively coupled to the second line port terminal 220c.

In some examples, the ninth conductive element 205i may be at least partly combined with, on integral to, the third conductive element 205c.

The adapter 200 also comprises a tenth conductive element 205j configured to couple a neutral terminal 230g of the first interface to a neutral terminal 220g of the second interface.

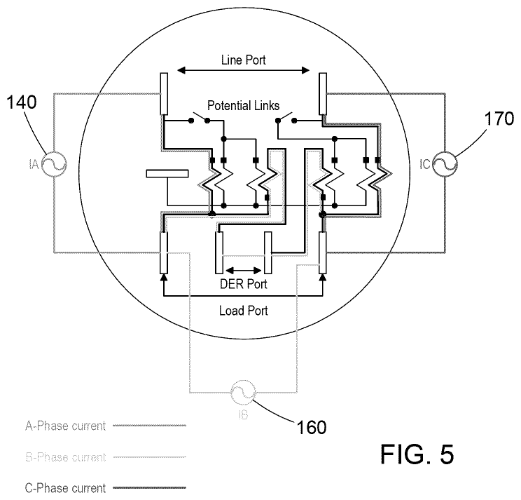

FIG. 5 depicts a method of testing the example three-port meter 100 wherein, in order to test the three-port meter, e.g. a form 43S meter, an adapter can be used to route the currents in a particular fashion that will emulate a common use of a three-port meter.

Such a method advantageously enables existing three-phase test boards and 3-phase reference standards that are widely used to test the three-port meter without a necessity for a new 4-phase reference standard and test board.

In this method, an adapter 300 is implemented to simulate a scenario where the load port is consuming energy from both DER and the line port, e.g. Grid. The current flows for that instance are illustrated in FIG. 5. In contrast to the example of FIG. 3, in this example the existing B-phase current element is used and directed it to blade 120c of the load port and blade 120d of the load port. Thus, the 4^{th} independent current phase is not required.

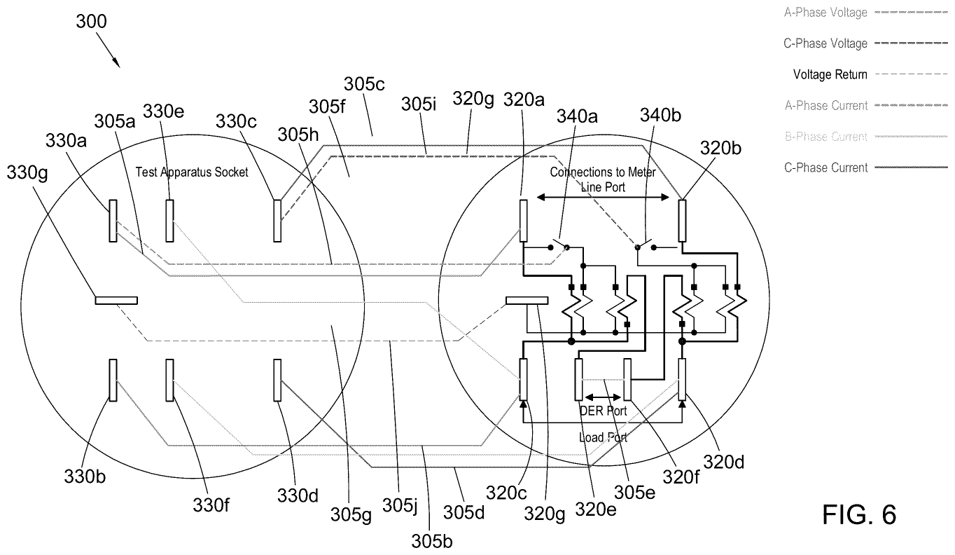

FIG. 6 depicts a configuration of an adapter 300 for implementing the method of FIG. 5, according to an embodiment of the disclosure. FIG. 6 represents an adapter 300 for coupling a three-port meter 100 to a three-phase meter test board.

The adapter 300 comprises a first interface for coupling to the three-phase meter test board, e.g. denoted “Test apparatus Socket” in FIG. 4. The adapter 300 comprises a second interface for coupling to the three-port meter, as denoted “Connection to meter” in FIG. 4.

The adapter 300 comprises a first conductive element 305a for coupling a first a-phase current source terminal 330a of the first interface to a first line port terminal 320a of the second interface.

The adapter 300 comprises a second conductive element 305b for coupling a second a-phase current source terminal 330b of the first interface to a first load port terminal 320c of the second interface.

The adapter 300 comprises a third conductive element 305c for coupling a first c-phase current source terminal 330c of the first interface to a second line port terminal of the second interface.

The adapter 300 comprises a fourth conductive element 305d for coupling a second c-phase current source terminal 330d of the first interface to a second load port terminal 320d of the second interface.

The adapter 300 comprises a fifth conductive element 305e for coupling a first distributed energy resource (DER) port terminal 320e of the second interface to a second DER port terminal 320f of the second interface.

The adapter 300 comprises a sixth conductive element 305f for coupling a first b-phase current source terminal 330e of the first interface to the first terminal 320c of the load port.

The adapter 300 comprises a seventh conductive element 305g for coupling a second b-phase current source terminal 330f of the first interface to the second terminal 320d of the load port.

In some examples, the adapter 300 also comprises an eighth conductive element 305h configured to couple an a-phase voltage source of the first interface to the second interface by coupling the first a-phase current source terminal 330a to a first terminal of a first potential link 340a, wherein a second terminal of the first potential link 340a is selectively coupled to the first line port terminal 320a.

In some examples, the eighth conductive element 305h may be at least partly combined with, on integral to, the first conductive element 305a.

In some examples, the adapter 300 also comprises a ninth conductive element 305i configured to couple a c-phase voltage source of the first interface to the second interface by coupling the first c-phase current source terminal 330c to a first terminal of a second potential link 340b, wherein a second terminal of the second potential link 340b is selectively coupled to the second line port terminal 320c.

In some examples, the ninth conductive element 305i may be at least partly combined with, on integral to, the third conductive element 305c.

The adapter 300 also comprises a tenth conductive element 305j configured to couple a neutral terminal 330g of the first interface to a neutral terminal 320g of the second interface.

Although the adapter 200 of FIG. 4 and the adapter 300 of FIG. 6 have been depicted as distinct adapters, it will be appreciated that in other embodiments of the disclosure, a single adapter may be configurable between the configurations of the adapter 200 of FIG. 4 and the adapter 300 of FIG. 6.

That is, in some embodiments an adapter may be implemented comprising at least one switch, relay or the like, for selectively configuring the adapter between: a first configuration for coupling the first and second b-phase current source terminals 230e, 230f of the first interface to the first and second terminals 220a, 220c of the line port respectively; or a second configuration for coupling the first and second b-phase current source terminals 230e, 2320f of the first interface to the first and second terminals 220c, 220d of the load port respectively.

Advantageously, the adapters 200, 300, or above-described combined adapter, allow a test board that only has three current elements to simultaneously send current from the line (grid), through both the load port and the DER port of the three-port meter.

The test board is able to get accurate energy measurements because it is sending current through the DER port using what would traditionally be the third current element for a three phase service.

That is, the disclosed adapter(s) effectively enable simultaneously testing of a flow of energy through all of the ports of a three-port meter simultaneously.

Although the disclosure has been described in terms of particular embodiments as set forth above, it should be understood that these embodiments are illustrative only and that the claims are not limited to those embodiments. Those skilled in the art will be able to make modifications and alternatives in view of the disclosure, which are contemplated as falling within the scope of the appended claims. Each feature disclosed or illustrated in the present specification may be incorporated in any embodiments, whether alone or in any appropriate combination with any other feature disclosed or illustrated herein.

### REFERENCE NUMERALS

100 three-port meter
105 line port
110 load port
115 DER port
120a-g blades
125 circuitry
130a,b potential links
140 a-phase current source
150 d-phase current source
160 b-phase current source
170 c-phase current source
200 adapter
205a first conductive element
205b second conductive element
205c third conductive element
205d fourth conductive element
205e fifth conductive element
205f sixth conductive element
205g seventh conductive element
205h eighth conductive element
205i ninth conductive element
205j tenth conductive element
220a first line port terminal
220b second line port terminal
220c first load port terminal
220d second load port terminal
220e first DER port terminal
220f second DER port terminal
230a first a-phase current source terminal
230b second a-phase current source terminal
230c first c-phase current source terminal
230d second c-phase current source terminal
230e first b-phase current source terminal
230f second b-phase current source terminal
230g neutral terminal
240a first potential link
240b second potential link
300 adapter
305a first conductive element
305b second conductive element
305c third conductive element
305d fourth conductive element
305e fifth conductive element
305f sixth conductive element
305g seventh conductive element
305h eighth conductive element
305i ninth conductive element
305j tenth conductive element
320a first line port terminal
320b second line port terminal
320c first load port terminal
320d second load port terminal
320e first DER port terminal
320g neutral terminal
3220f second DER port terminal
330a first a-phase current source terminal
330b second a-phase current source terminal
330c first c-phase current source terminal
330d second c-phase current source terminal
330e first b-phase current source terminal
330f second b-phase current source terminal
330g neutral terminal
340a first potential link
340b second potential link

1. An adapter (200, 300) for coupling a three-port meter to a three-phase meter test board, the adapter comprising:
a first interface for coupling to the three-phase meter test board;
a second interface for coupling to the three-port meter;
first and second conductive elements (205a, 205b, 305a, 305b) for coupling first and second a-phase current source terminals (230a, 230b, 330a, 330b) of the first interface to a first line port terminal (220a, 320a) and a first load port terminal (220c, 320c) of the second interface respectively;
third and fourth conductive elements (205c, 205d, 305c, 305d) for coupling first and second c-phase current source terminals (230c, 230d, 330c, 330d) of the first interface to a second line port terminal (220b, 3200b) and a second load port terminal (220d, 320d) of the second interface respectively;
a fifth conductive element (205e, 305e) for coupling a first distributed energy resource (DER) port terminal (220e, 320e) of the second interface to a second DER port terminal (220f, 320f) of the second interface; and
sixth and seventh conductive elements (205f, 205g, 305f, 305g) for coupling first and second b-phase current source terminals (230e, 230f, 330e, 330f) of the first interface to the first and second terminals of the line port (220a, 220b, 320a, 320b) respectively or to the first and second terminals of the load port (220c, 220d, 320c, 320d) respectively.

2. The adapter (200, 300) of claim 1, comprising at least one switch for selectively configuring the adapter between:
a first configuration for coupling the first and second b-phase current source terminals (230e, 230f, 330e, 330f) of the first interface to the first and second terminals (220a, 220b, 320a, 320b) of the line port respectively; or
a second configuration for coupling the first and second b-phase current source terminals (230e, 230f, 330e, 330f) of the first interface to the first and second terminals of the load port (220c, 220d, 320c, 320d) respectively.

3. The adapter (200, 300) of claim 1, configured to couple an a-phase voltage source of the first interface to the second interface by coupling the first a-phase current source terminal (230a, 320a) to a first terminal of a first potential link 240a, 340a), wherein a second terminal of the first potential link is selectively coupled to the first line port terminal (220a, 320a).

4. The adapter (200, 300) of claim 1, configured to couple a c-phase voltage source of the first interface to the second interface by coupling the first c-phase current source terminal (230c, 330c) to a first terminal of a second potential link (240b, 340b), wherein a second terminal of the second potential link is selectively coupled to the second line port terminal (220b, 320b).

5. The adapter (200, 300) of claim 1, comprising a further conductive element (205j, 305j) configured to couple a neutral terminal of the first interface to a neutral terminal of the second interface.

6. The adapter (200, 300) of claim 1, wherein the first interface comprises a plurality of blades for being received by a meter socket on the three-phase meter test board, each blade coupled to one of the first to seventh conductive elements.

7. The adapter (200, 300) of claim 1, wherein the second interface comprises a plurality of sockets for received blades of the three-phase meter, each socket coupled to one of the first to seventh conductive elements.

8. A meter test system comprising:
a three-phase meter test board; and
an adapter (200, 300) according to claim 1, wherein the adapter is received by the three-phase meter test board and configured to receive the three-port meter.

9. The meter test system of claim 8, wherein the three-phase meter test board comprises an a-phase current source, a b-phase current source and a c-phase current source, and wherein the current sources are floating and electrically isolated from each other.

10. The meter test system of claim 8, comprising the three-phase meter (100), and optionally wherein the three-phase meter conforms to meter form 43S as defined by the American National Standard for Physical Aspects of Watt-hour Meters (ANSI) C12.10.

11. A method of testing a three-port meter using a three-phase meter test board, the method comprising using an adapter (200, 300) according to claim 1 to couple the three-port meter to a three-phase meter test board.

12. The method according to claim 11, comprising a step of configuring the adapter in:
a first configuration for coupling the first and second b-phase current source terminals of the first interface to the first and second terminals of the line port respectively; or
a second configuration for coupling the first and second b-phase current source terminals of the first interface to the first and second terminals of the line port respectively.

13. The method of claim 11 when in the first configuration, comprising configuring a-phase, b-phase and c-phase current sources of the three-phase meter test board to simulate a simultaneous flow of energy from the DER port to the line port of the meter and the line port to the load port of the meter.

14. The method of claim 11 when in the second configuration, comprising configuring a-phase, b-phase and c-phase current sources of the three-phase meter test board to simulate a simultaneous flow of energy from the DER port to the load port of the meter and the line port to the load port of the meter.

15. The method of claim 13, comprising a preceding step of configuring a/the first potential link and/or a/the second potential link of the adapter to avoid a short circuit through the b-phase current source.
